(19) United States
(12) Patent Application Publication
(10) Pub. No.: US 2020/0312623 A1
(43) Pub. Date: Oct. 1, 2020

(54) SUBSTRATE PROCESSING APPARATUS AND SUBSTRATE PROCESSING METHOD

(71) Applicant: TOKYO ELECTRON LIMITED, Tokyo (JP)

(72) Inventors: Kazuki MOYAMA, Miyagi (JP); Kazuya NAGASEKI, Miyagi (JP); Shinji HIMORI, Miyagi (JP); Michishige SAITO, Miyagi (JP); Gen TAMAMUSHI, Miyagi (JP)

(73) Assignee: TOKYO ELECTRON LIMITED, Tokyo (JP)

(21) Appl. No.: 16/834,612

(22) Filed: Mar. 30, 2020

(30) Foreign Application Priority Data
Apr. 1, 2019 (JP) 2019-070022

(51) Int. Cl. H01J 37/32; H01L 21/3065; H01L 21/683; H01L 21/67; C23C 16/455

(52) U.S. Cl. CPC H01J 37/3244; H01J 37/32715; C23C 16/45565; H01L 21/683; H01L 21/67098; H01L 21/3065

(57) ABSTRACT

A substrate processing apparatus includes a processing chamber that accommodates a substrate, a gas supply having a gas diffusion chamber and a plurality of gas holes that communicates the gas diffusion chamber with the processing chamber, a gas inlet tube that introduces a gas into the gas diffusion chamber of the gas supply, and a gas source connected to the gas inlet tube and supplies the gas to the gas inlet tube. The gas supply has a volume variable device for changing a volume in the gas diffusion chamber.

### CROSS-REFERENCE TO RELATED APPLICATIONS

This application is based on and claims priority from Japanese Patent Application No. 2019-070022, filed on Apr. 1, 2019 with the Japan Patent Office, the disclosure of which is incorporated herein in its entirety by reference.

### TECHNICAL FIELD

The present disclosure relates to a substrate processing apparatus and a substrate processing method.

### BACKGROUND

In a conventional manufacturing process of a semiconductor device, there is a process of exchanging multiple process gases to repeat lamination and removal of films with respect to a substrate. See, for example, Japanese Patent No. 5709344.

### SUMMARY

One aspect of the present disclosure is directed to a substrate processing apparatus including a processing chamber, a gas supply, a gas inlet tube and a gas source. The processing chamber accommodates a substrate. The gas supply has a gas diffusion chamber and a plurality of gas holes that communicates the gas diffusion chamber with the processing chamber. The gas inlet tube is at least one gas inlet tube for introducing a gas into the gas diffusion chamber of the gas supply. The gas source is connected to the gas inlet tube and supplies the gas to the gas inlet tube. In addition, the gas supply has a volume-variable device for changing a volume in the gas diffusion chamber.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a substrate processing apparatus according to an embodiment of the present disclosure.

FIG. 2A is a view illustrating an example of a substrate processing method according to the present embodiment.

FIG. 2B is a view illustrating an example of a substrate processing method according to the present embodiment.

FIG. 2C is a view illustrating an example of a substrate processing method according to the present embodiment.

FIG. 2D is a view illustrating an example of a substrate processing method according to the present embodiment.

FIG. 3 is a view illustrating an example of an operation state of each portion of a substrate processing apparatus according to the present embodiment.

FIG. 4A is a view illustrating an example of a substrate processing method according to Modification 1.

FIG. 4B is a view illustrating an example of a substrate processing method according to Modification 1.

FIG. 4C is a view illustrating an example of a substrate processing method according to Modification 1.

FIG. 4D is a view illustrating an example of a substrate processing method according to Modification 1.

FIG. 5 is a view illustrating an example of an operation state of each portion of a substrate processing apparatus according to Modification 1.

FIG. 6A is a view illustrating an example of a substrate processing method according to Modification 2.

FIG. 6B is a view illustrating an example of a substrate processing method according to Modification 2.

FIG. 6C is a view illustrating an example of a substrate processing method according to Modification 2.

FIG. 6D is a view illustrating an example of a substrate processing method according to Modification 2.

FIG. 7 is a view illustrating an example of an operation state of each portion of a substrate processing apparatus according to Modification 2.

FIG. 8 is a view illustrating an example of a substrate processing apparatus according to Modification 3.

### DESCRIPTION OF EMBODIMENT

In the following detailed description, reference is made to the accompanying drawing, which form a part hereof The illustrative embodiments described in the detailed description, drawing, and claims are not meant to be limiting. Other embodiments may be utilized, and other changes may be made without departing from the spirit or scope of the subject matter presented here.

Hereinafter, a detailed configuration of a substrate processing apparatus and a substrate processing method according to the present disclosure will be described with reference to the accompanying drawings. Meanwhile, techniques of the present disclosure are not limited by the following embodiments.

In the related art, when a plurality of process gases, for example, two kinds of process gases including a gas A and a gas B, are exchanged, the processing chamber is started to be exhausted after the supply of the gas A is stopped, and the gas B is started to be supplied after the gas A is exhausted. For this reason, mutual exchange between the gas A and the gas B takes time. In this regard, it is proposed to exchange process gases at high speed by partitioning a gas distribution member, which is adjacent to a surface of a substrate, into an inner section and an outer section, and supplying different kinds of process gases to the inner section and the outer section, respectively. However, when the gas distribution member is partitioned to exchange the process gases, it is still difficult to shorten the time for exhausting the process gas from the processing chamber. Accordingly, it is expected to shorten the time for exhausting the process gas.

### Overall Configuration of Substrate Processing Apparatus 10

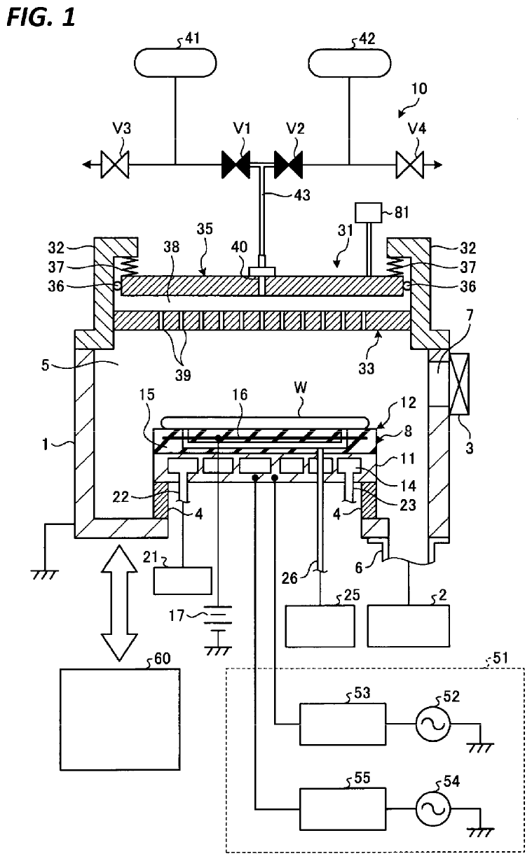

FIG. 1 is a view illustrating an example of a substrate processing apparatus according to an embodiment of the present disclosure. The substrate processing apparatus 10 illustrated in FIG. 1 is a capacitively coupled plasma processing apparatus. The substrate processing apparatus 10 has a chamber 1, an exhaust device 2 and a gate valve 3. The chamber 1 is formed of, for example, aluminum. The chamber 1 is formed in a cylindrical shape and is anodized (anodic oxidation treatment) on its surface. The chamber 1 is electrically grounded. Inside the chamber 1, a processing chamber 5, which is a processing space, is formed. The chamber 1 isolates the processing chamber 5 from the external atmosphere. An exhaust outlet 6 and an opening 7 are further formed at the chamber 1. The exhaust outlet 6 is formed at a bottom of the chamber 1. The opening 7 is formed at a side wall of the chamber 1. The exhaust device 2 is connected to the processing chamber 5 of the chamber 1 through the exhaust outlet 6. The exhaust device 2 exhausts gas from the processing chamber 5 through the exhaust outlet 6. The gate valve 3 opens the opening 7 or closes the opening 7.

The substrate processing apparatus 10 further has a stage 8. The stage 8 is disposed in the processing chamber 5 and is installed at the bottom of the chamber 1 through a support member 4. The stage 8 has a support base 11 and an electrostatic chuck 12. The support base 11 is formed of a conductor such as, for example, aluminum (Al), titanium (Ti), or silicon carbide (SiC). The support base 11 is supported by the chamber 1 through the support member 4 which is in contact with a periphery of a lower surface of the support member 11. The support member 4 is formed of an insulator and is formed in a ring state. The support member 4 is disposed such that an opening formed in the bottom of the chamber 1 is closed by the support member 4 together with the stage 8. Inside the support base 11 is formed a coolant flow path 14. The electrostatic chuck 12 is disposed on or above the support base 11 and is supported by the support base 11. The electrostatic chuck 12 has an electrostatic chuck main body 15 and a chuck electrode 16. The electrostatic chuck main body 15 is formed of an insulator. The electrostatic chuck 12 is formed by embedding the chuck electrode 16 inside the electrostatic chuck main body 15. The substrate processing apparatus 10 further has a direct current (DC) voltage source 17. The DC voltage source 17 is electrically connected to the chuck electrode 16 and supplies a DC current to the chuck electrode 16.

The substrate processing apparatus 10 further has a chiller 21, a coolant inlet pipe 22, and a coolant outlet pipe 23. The chiller 21 is connected to the coolant flow path 14 through the coolant inlet pipe 22 and the coolant outlet pipe 23. The chiller 21 cools a coolant of which examples are cooling water or brine, and cools the electrostatic chuck 12 of the stage 8 by circulating the cooled coolant in the coolant flow path 14 through the coolant inlet pipe 22 and the coolant outlet pipe 23.

The substrate processing apparatus 10 further has a heat transfer gas source 25 and a heat transfer gas supply line 26. The heat transfer gas supply line 26 is formed such that an end thereof is formed on an upper surface of the electrostatic chuck 12. The heat transfer gas source 25 supplies a heat transfer gas of which examples are helium gas (He) or argon gas (Ar) to the heat transfer gas supply line 26 and supplies the heat transfer gas between the electrostatic chuck 12 and a wafer W that is placed on the stage 8.

The substrate processing apparatus 10 further has a gas supply 31 and a top plate support 32. The gas supply 31 has a shower plate 33, a top plate 35, a sealing member 36, and a bellows 37. The top plate support 32 is formed of, for example, aluminum. The top plate support 32 is formed in a cylindrical shape that may be disposed on or above the side wall of the chamber 1 and is anodized (anodic oxidation treatment) on its surface. The top plate support 32 connects with the top plate 35 through the bellows 37.

The shower plate 33 is formed of a conductor and is formed in a disc shape. The shower plate 33 is disposed such that it faces the stage 8 and that a plane along a lower surface of the shower plate 33 is substantially parallel to a plane along an upper surface of the stage 8. In addition, the shower plate 33 is disposed to close the opening formed in a ceiling of the chamber 1. The shower plate 33 is supported by the chamber 1 through the top plate support 32 such that the shower plate 33 and the chamber 1 are electrically connected to each other.

The top plate 35 is formed of a conductor and is formed in a disc shape. The top plate 35 is disposed such that it faces the shower plate 33 and that a plane along a lower surface of the top plate 35 is substantially parallel to a plane along an upper surface of the shower plate 33. In addition, the top plate 35 has a driving device 81. The driving device 81 may be an actuator, a motor, an air cylinder and/or other device that controllably urges the top plate 35 upward and downward with respect to the shower plate 33. The sealing member 36 is formed of a flexible material and is formed in a ring shape. The sealing member 36 moves together with the top plate 35 when the top plate 35 moves up and down, while maintaining the airtightness between a periphery of the top plate 35 and the top plate support 32. The top plate 35 forms a gas diffusion chamber 38, together with the top plate support 32, the shower plate 33 and the sealing member 36.

The bellows 37 is formed to be expansible. The bellows 37 connects with a flange portion of the top plate support 32, and an upper surface of the periphery of the top plate 35. The top plate 35 is moved up and down by the driving device 81. That is, the gas supply 31 is capable of changing a volume of the gas diffusion chamber 38 by moving the top plate 35 up and down. In other words, the gas supply 31 is an example of a gas supply that has a volume-variable device. The gas diffusion chamber 38 may be divided into regions, for example, a center portion and a peripheral portion, as described below, and their volumes may be individually changed by respective corresponding top plates. In addition, the volume of the gas diffusion chamber 38 may be changed not only by the vertical movement of the top plate 35 but also by, for example, a balloon or a piston provided in the gas diffusion chamber 38.

In the shower plate 33, gas supply holes 39 is formed to communicate the processing chamber 5 with the gas diffusion chamber 38 are formed. The gas supply hole 39 is an example of a gas hole. A gas inlet 40 is formed in the center of the top plate 35 and communicates with the gas diffusion chamber 38.

The substrate processing apparatus 10 further has process gas sources 41 and 42. The process gas sources 41 and 42 are connected to a gas inlet tube 43 through gas pipes having valves V1 and V2, respectively, and the gas inlet tube 43 is connected to the gas inlet 40. The process gas sources 41 and 42 supply a predetermined process gas to the gas inlet 40. The process gas may include a plurality of gases. The process gas is a gas such as a fluorine-containing gas or an oxygen-containing gas. In addition, the process gas may further be added with a predetermined compound. Examples of such a compound include a compound containing hydrogen, nitrogen, and/or chlorine. A part of the gas inlet tube 43 is expansible or movable in accordance with the vertical movement of the top plate 35. The gas inlet tube 43 may use, for example, a flexible tube. The gas inlet 40 and the gas inlet tube 43 may be provided in plurality. Valves V3 and V4 are connected between the process gas sources 41 and 42 and the valves V1 and V2, respectively, and other ends thereof are connected to the exhaust device 2. The valves V3 and V4 are opened when the valves V1 and V2 are closed respectively.

The support base 11 of the stage 8 is used as a bottom electrode, and the shower plate 33 is used as a top electrode. The substrate processing apparatus 10 further has a power supply device 51. The power supply device 51 has a first radio-frequency power source 52, a first matcher 53, a second radio-frequency power source 54 and a second matcher 55. The first radio-frequency power source 52 is connected to the stage 8 through the first matcher 53. The first radio-frequency power source 52 supplies, to the support base 11 of the stage 8, a first radio-frequency power of a first frequency (for example, 40 MHz) at a predetermined power. The first matcher 53 matches a load impedance to an internal (or output) impedance of the first radio-frequency power source 52. The first matcher 53 serves such that the internal impedance of the first radio-frequency power source 52 and the load impedance match with each other in appearance when a plasma is generated in the processing chamber 5.

The second radio-frequency power source 54 is connected to the stage 8 through the second matcher 55. The second radio-frequency power source 54 supplies, to the stage 8, a second radio-frequency power of a second frequency (for example, 0.4 MHz) that is lower than the first frequency at a predetermined power. The second matcher 55 matches a load impedance to an internal (or output) impedance of the second radio-frequency power source 54. The second matcher 55 serves such that the internal impedance of the second radio-frequency power source 54 and the load impedance match with each other in appearance when a plasma is generated in the processing chamber 5.

The substrate processing apparatus 10 may further have a controller 60. The controller 60 may be a computer having a processor, a memory, an input device, and a display device. The controller 60 controls each portion of the substrate processing apparatus 10. In the controller 60, an operator may perform, for example, a command input operation by using an input device in order to manage the substrate processing apparatus 10. In addition, the controller 60 may visualize and display an operation state of the substrate processing apparatus 10 with a display device. In the memory of the controller 60 are stored a control program for controlling, with the processor, various processings performed by the substrate processing apparatus 10, and recipe data. As the processor of the controller 60 executes the control program and controls each portion of the substrate processing apparatus 10 according to the recipe data, desired processing is performed by the substrate processing apparatus 10.

For example, the controller 60 controls each portion of the substrate processing apparatus 10 such that the processing may be performed by alternately repeating two kinds of process gases. As a detailed example, the controller 60 lowers the top plate 35 and closes valves V1 and V2, thereby performing an exhaust process in a state that the volume of the gas diffusion chamber 38 is reduced. The controller 60 lifts the top plate 35 to increase the volume of the gas diffusion chamber 38 and opens the valve V1 to introduce the gas A from the process gas source 41, thereby performing a deposition process on the wafer W by a plasma of the gas A. The controller 60 lowers the top plate 35 and closes valves V1 and V2, thereby performs a process of exhausting the gas A in a state that the volume of the gas diffusion chamber 38 is reduced. The controller 60 lifts the top plate 35 to increase the volume of the gas diffusion chamber 38, opens the valve V2 to introduce the gas B from the process gas source 42, thereby performing an etching process on the wafer W by a plasma of the gas B. The controller 60 lowers the top plate 35 and closes valves V1 and V2, thereby performing a process of exhausting the gas B in a state that the volume of the gas diffusion chamber 38 is reduced. The controller 60 repeats these processes a desired number of times.

### Substrate Processing Method

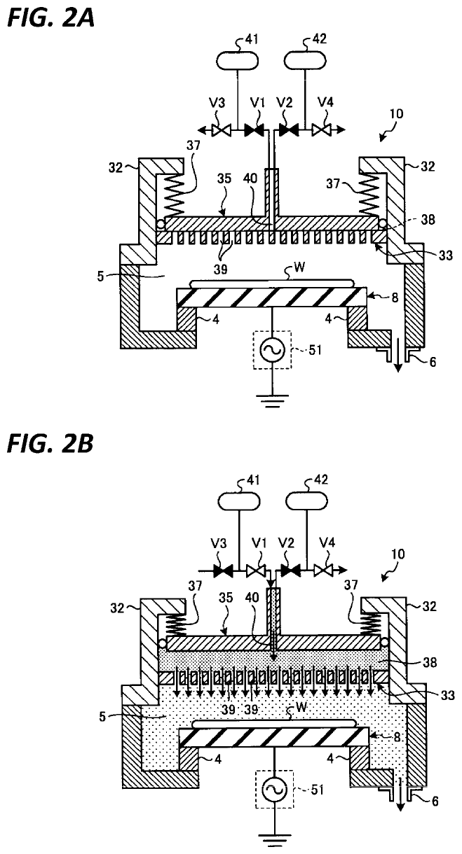

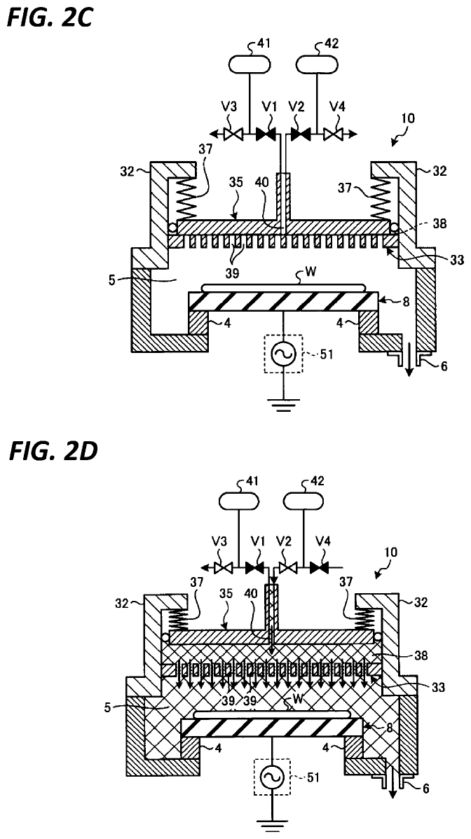

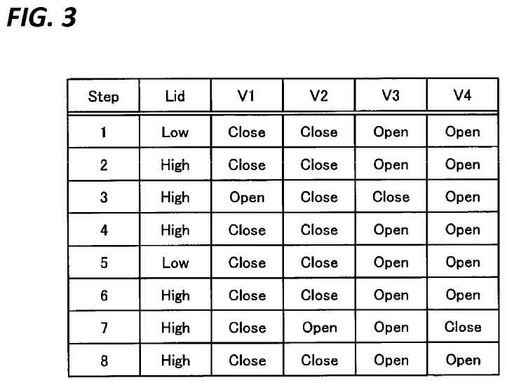

Hereinafter, a substrate processing method according to the present embodiment will be described. FIGS. 2A to 2D are views illustrating an example of a substrate processing method according to the present embodiment. FIG. 3 is a view illustrating an example of an operation state of each portion of a substrate processing apparatus according to the present embodiment. In FIG. 3, a processing process is denoted as “Step,” the top plate 35 is denoted as “Lid,” and states of valves V1 to V4 in each process are illustrated. In addition, the process gas sources 41 and 42 supply the gas A and the gas B, respectively.

In the substrate processing method according to the present embodiment, first, the controller 60 controls the gate valve 3 to open the opening 7. When the opening 7 is opened, a wafer W is loaded into the processing chamber 5 of the chamber 1 through the opening 7 and placed on the stage 8. The controller 60 controls the gate valve 3 to close the opening 7 after the wafer W is placed on the stage 8. In addition, the controller 60 controls the DC voltage source 17 to apply a DC voltage to the chuck electrode 16. The wafer W is held by the electrostatic chuck 12 by a Coulomb force when the DC voltage is applied to the chuck electrode 16.

As illustrated in FIG. 2A, the controller 60 closes the valves V1 and V2 and controls the driving device 81 (not illustrated in FIG. 2A) of the top plate 35 to lower the top plate 35, thereby reducing the volume of the gas diffusion chamber 38. When the opening 7 is closed and the volume of the gas diffusion chamber 38 is reduced, the controller 60 controls the exhaust device 2 to exhaust the gas from the processing chamber 5 through the exhaust outlet 6 such that an atmosphere of the processing chamber 5 has a predetermined degree of vacuum (Step 1 in FIG. 3). In Step 1, the top plate 35 is positioned at a lower position (Low), the valves V1 and V2 are closed, and the valves V3 and V4 are opened. When the exhausting is completed, the controller 60 controls the driving device of the top plate 35 to lift the top plate 35. The controller 60 moves the top plate 35 to an upper position (High) and increases the volume of the gas diffusion chamber 38 (Step 2 in FIG. 3).

When the wafer W is held by the electrostatic chuck 12, the controller 60 controls the heat transfer gas source 25 to supply a heat transfer gas to the heat transfer gas supply line 26 and supply the heat transfer gas between the electrostatic chuck 12 and the wafer W. The controller 60 further controls the chiller 21 and cools the electrostatic chuck 12 by circulating the coolant, which is cooled to a predetermined temperature, in the coolant flow path 14. In such a case, the supplied heat transfer gas is interposed between the electrostatic chuck 12 and the wafer W, and the heat is transferred from the electrostatic chuck 12 to the wafer W, such that the wafer W is adjusted in terms of temperature such that the temperature of the wafer W is included in a predetermined temperature range.

Next, as illustrated in FIG. 2B, when the temperature of the wafer W is adjusted to a predetermined temperature, the controller 60 controls the process gas source 41 and the valves V1 and V3 such that the valve V1 is opened, the valve V3 is closed, and the gas A is supplied to the gas inlet 40. The gas A is supplied from the gas inlet 40 to the gas diffusion chamber 38 and diffused in the gas diffusion chamber 38. After the gas A is diffused in the gas diffusion chamber 38, the gas A is supplied in a shower manner to the processing chamber 5 of the chamber 1 through the gas supply holes 39 (Step 3 in FIG. 3).

The controller 60 controls the power supply device 51 to supply the first radio-frequency power for plasma excitation to the stage 8. In the processing chamber 5, a plasma is generated as the first radio-frequency power is supplied to the stage 8. The wafer W is processed by the plasma generated from the gas A in the processing chamber 5. For example, a film is formed on the wafer W by the plasma generated from the gas A. When the processing by the gas A is completed, the controller 60 controls the valves V1 and V3 such that the valve V1 is closed, the valve V3 is opened, and the supply of the gas A is stopped (Step 4: FIG. 3). In addition, the controller 60 controls the power supply device 51 to stop supplying a radio-frequency power to the processing chamber 5.

Subsequently, as illustrated in FIG. 2C, the controller 60 controls the driving device 81 (not illustrated in FIG. 2C) of the top plate 35 to lower the top plate 35, thereby reducing the volume of the gas diffusion chamber 38. When the volume of the gas diffusion chamber 38 is reduced, the controller 60 controls the exhaust device 2 to exhaust the gas A from the processing chamber 5 (Step 5 in FIG. 3). In Step 5, the top plate 35 is positioned at the lower position (Low), the valves V1 and V2 are closed, and the valves V3 and V4 are opened. When exhausting of the gas A is completed, the controller 60 controls the driving device of the top plate 35 to lift the top plate 35. The controller 60 moves the top plate 35 to the upper position (High) to increase the volume of the gas diffusion chamber 38 (step 6 in FIG. 3).

Next, as illustrated in FIG. 2D, the controller 60 controls the process gas source 42 and the valves V2 and V4 such that the valve V2 is opened, the valve V4 is closed, and the gas B is supplied to the gas inlet 40. The gas B is supplied from the gas inlet 40 to the gas diffusion chamber 38 and diffused in the gas diffusion chamber 38. After the gas B is diffused in the gas diffusion chamber 38, the gas B is supplied in a shower manner to the processing chamber 5 of the chamber 1 through the gas supply holes 39 (Step 8 in FIG. 3).

The controller 60 controls the power supply device 51 to supply the first radio-frequency power for plasma excitation and the second radio-frequency power for biasing to the stage 8. The controller 60 generates a plasma similarly to the case of the gas A. An ion in the plasma is accelerated toward the wafer W, since the second radio-frequency power is supplied to the stage 8. The wafer W is processed by the plasma generated from the gas B in the processing chamber 5. For example, the wafer W is etched by the plasma generated from the gas B. When the processing by the gas B is completed, the controller 60 controls the valves V2 and V4 such that the valve V2 is closed, the valve V4 is opened, and the supply of the gas B is stopped (Step 8 in FIG. 3). In addition, the controller 60 controls the power supply device 51 to stop supplying a radio-frequency power to the processing chamber 5. The controller 60 then repeats the processing, for example, in a scheme such as exhaust, processing by gas A, exhaust, processing by gas B, and exhaust.

When the series of repetitive processing ends, the controller 60 controls the DC voltage source 17 such that a DC voltage of a positive negative relation opposite to that at the time of absorbing the wafer W is applied to the chuck electrode 16. As the opposite DC voltage is applied to the chuck electrode 16, the static electricity of the wafer W is removed, and the wafer W is dechucked from the electrostatic chuck 12. The controller 60 further controls the gate valve 3 to open the opening 7. The wafer W is carried out from the processing chamber 5 of the chamber 1 through the opening 7 when the opening 7 is opened.

In the present embodiment, since the volume of the gas diffusion chamber 38 is reduced by lowering the top plate 35, the time for exhausting the process gas can be shortened.

### Modification 1

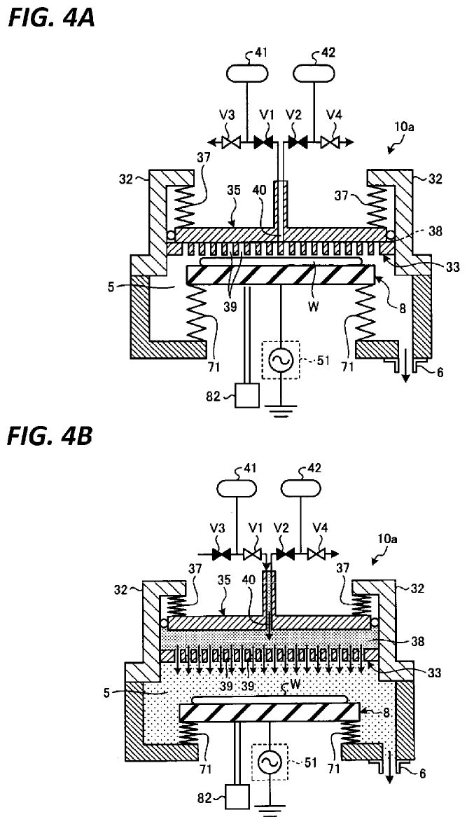

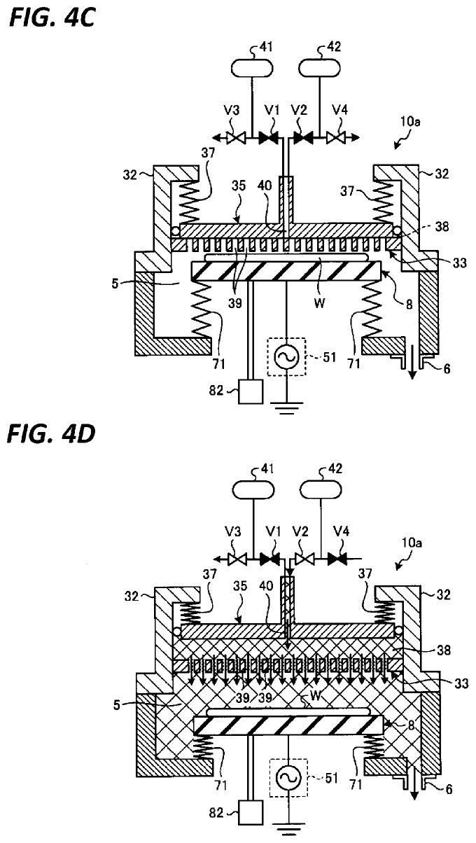

Next, a substrate processing method according to Modification 1 will be described. FIGS. 4A to 4D are views illustrating an example of a substrate processing method according to Modification 1. FIGS. 4A to 4D are an example of a case where a substrate processing apparatus 10a in which the stage 8 of the substrate processing apparatus 10 moves up and down is used. In the substrate processing apparatus 10a, a bellows 71 connects with the stage 8 and a bottom of the chamber 1 is provided instead of the support member 4 of the substrate processing apparatus 10. In addition, the stage 8 has a driving device 82 that drives the stage 8 up and down. The driving device 82 may be an actuator, a motor, an air cylinder and/or other device that controllably urges the stage 8 upward and downward with respect to the bottom of the chamber 1. In the substrate processing apparatus 10a, the same configurations as those of the substrate processing apparatus 10 will be denoted as the same reference numerals, and descriptions of the repeated configurations and operations will be omitted.

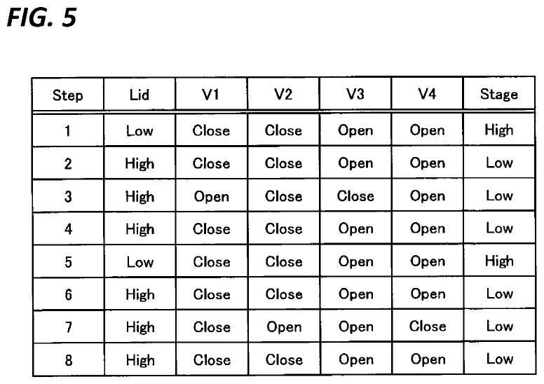

FIG. 5 is a view illustrating an example of an operation state of each portion of a substrate processing apparatus according to Modification 1. In FIG. 5, a processing process is denoted as “Step,” the stage 8 is denoted as “Stage,” the top plate 35 is denoted as “Lid,” and states of valves V1 to V4 in each process are illustrated. In addition, the process gas sources 41 and 42 supply the gas A and the gas B, respectively.

In the substrate processing method according to Modification 1, as illustrated in FIG. 4A, the controller 60 closes the valves V1 and V2 and controls the driving device 81 (not illustrated in FIG. 4A) of the top plate 35 to lower the top plate 35, thereby reducing the volume of the diffusion chamber 38. In addition, the controller 60 controls the driving device 82 of the stage 8 to lift the stage 8, thereby reducing the volume of the processing chamber 5. When the opening 7 is closed and the volumes of the processing chamber 5 and the gas diffusion chamber 38 are reduced, the controller 60 controls the exhaust device 2 to exhaust the gas from the processing chamber 5 through the exhaust outlet 6 such that an atmosphere of the processing chamber 5 has a predetermined degree of vacuum (Step 1 in FIG. 5). In Step 1, the stage 8 is positioned at an upper position (High), the top plate 35 is positioned at a lower position (Low), the valves V1 and V2 are closed, and the valves V3 and V4 are opened. When the exhausting is completed, the controller 60 controls the driving device 82 of the stage 8 to lower the stage 8 and controls the driving device 81 of the top plate 35 to lift the top plate 35. The controller 60 moves the stage 8 to the lower position (Low) and moves the top plate 35 to the upper position (High), thereby increasing the volume of the gas diffusion chamber 38 (Step 2 in FIG. 5).

Next, as illustrated in FIG. 4B, the controller 60 controls the process gas source 41 and the valves V1 and V3 such that the valve V1 is opened, the valve V3 is closed, and the gas A is supplied to the gas inlet 40. The gas A is supplied from the gas inlet 40 to the gas diffusion chamber 38 and diffused in the gas diffusion chamber 38. After the gas A is diffused in the gas diffusion chamber 38, the gas A is supplied in a shower manner to the processing chamber 5 of the chamber 1 through the gas supply holes 39 (Step 3 in FIG. 5).

The controller 60 controls the power supply device 51 to supply the first radio-frequency power for plasma excitation to the stage 8. The controller 60 generates a plasma. The wafer W is processed by the plasma generated from the gas A in the processing chamber 5. For example, a film is formed on the wafer W by the plasma generated from the gas A. When the processing by the gas A is completed, the controller 60 controls the valves V1 and V3 such that the valve V1 is closed, the valve V3 is opened, and the supply of the gas A is stopped (Step 4 in FIG. 5). In addition, the controller 60 controls the power supply device 51 to stop supplying a radio-frequency power to the processing chamber 5.

Subsequently, as illustrated in FIG. 4C, the controller 60 controls the driving device 81 (not illustrated in FIG. 4C) of the top plate 35 to lower the top plate 35, thereby reducing the volume of the gas diffusion chamber 38. The controller 60 further controls the driving device 82 of the stage 8 to lift the stage 8, thereby reducing the volume of the processing chamber 5. When the volumes of the processing chamber 5 and the gas diffusion chamber 38 are reduced, the controller 60 controls the exhaust device 2 to exhaust the gas A from the processing chamber 5 (Step 5 in FIG. 5). In Step 5, the stage 8 is positioned at the upper position (High), the top plate 35 is positioned at the lower position (Low), the valves V1 and V2 are closed, and the valves V3 and V4 are opened. When exhausting is completed, the controller 60 controls the driving device 82 of the stage 8 to lower the stage 8 and controls the driving device 81 of the top plate 35 to lift the top plate 35. The controller 60 moves the stage 8 to the lower position (Low) and moves the top plate 35 to the upper position (High), thereby increasing the volume of the gas diffusion chamber 38 (Step 6 in FIG. 5).

Next, as illustrated in FIG. 4D, the controller 60 controls the process gas source 42 and the valves V2 and V4 such that the valve V2 is opened, the valve V4 is closed, and the gas B is supplied to the gas inlet 40. The gas B is supplied from the gas inlet 40 to the gas diffusion chamber 38 and diffused in the gas diffusion chamber 38. After the gas B is diffused in the gas diffusion chamber 38, the gas B is supplied in a shower manner to the processing chamber 5 of the chamber 1 through the gas supply holes 39 (Step 7 in FIG. 5).

The controller 60 controls the power supply device 51 to supply the first radio-frequency power for plasma excitation and the second radio-frequency power for biasing to the stage 8. The controller 60 generates a plasma. The wafer W is processed by the plasma generated from the gas B in the processing chamber 5. For example, the wafer W is etched by the plasma generated from the gas B. When the processing by the gas B is completed, the controller 60 controls the valves V2 and V4 such that the valve V2 is closed, the valve V4 is opened, and the supply of the gas B is stopped (Step 8 in FIG. 5). In addition, the controller 60 controls the power supply device 51 to stop supplying a radio-frequency power to the processing chamber 5. The controller 60 then repeats the processing, for example, in a scheme such as exhaust, processing by gas A, exhaust, processing by gas B, and exhaust.

In Modification 1, the stage 8 is lifted to reduce the volume of the processing chamber 5 and the top plate 35 is lowered to reduce the volume of the gas diffusion chamber 38, and thus the time for exhausting the process gas can be further shortened.

### Modification 2

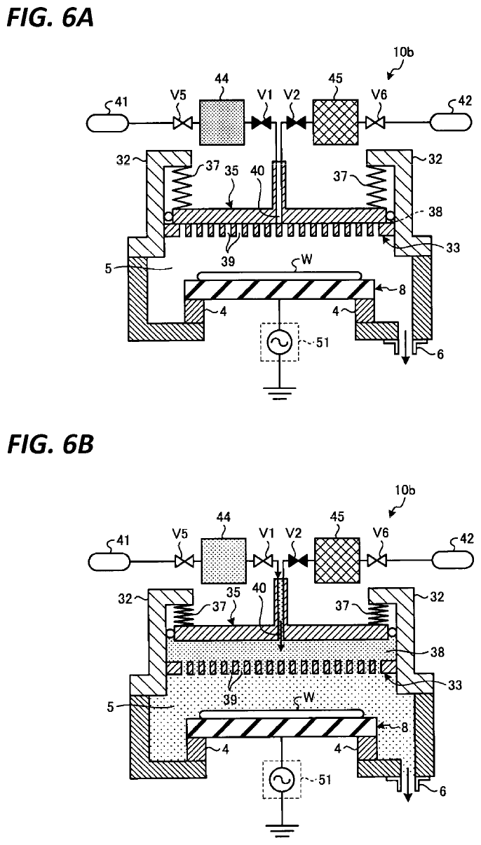

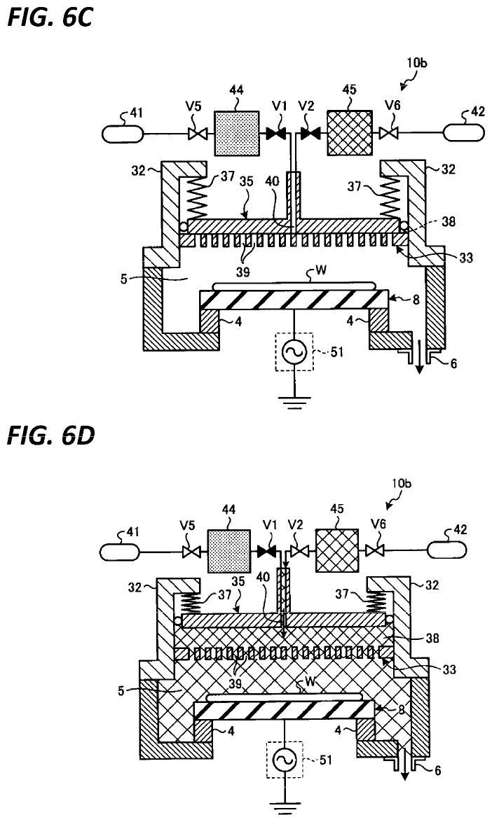

Next, a substrate processing method according to Modification 2 will be described. FIGS. 6A to 6D are views illustrating an example of a substrate processing method according to Modification 2. FIGS. 6A to 6D are an example of a substrate processing apparatus 10b that have valves V5 and V6 and gas buffers 44 and 45 between the process gas sources 41 and 42 and the valves V1 and V2 of the substrate processing apparatus 10, respectively. In the substrate processing apparatus 10b, the same configurations as those of the substrate processing apparatus 10 will be denoted as the same reference numerals, and descriptions of the repeated configurations and operations will be omitted.

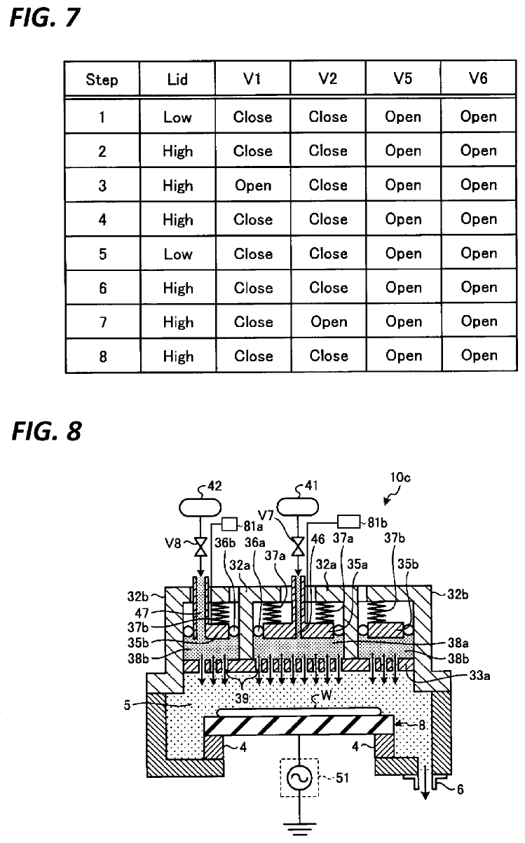

FIG. 7 is a view illustrating an example of an operation state of each portion of a substrate processing apparatus according to Modification 2. In FIG. 7, a processing process is denoted as “Step,” the top plate 35 is denoted as “Lid,” and states of valves V1, V2, V5, and V6 in each process are illustrated. In addition, the process gas sources 41 and 42 supply the gas A and the gas B, respectively.

In the substrate processing method according to Modification 2, as illustrated in FIG. 6A, the controller 60 closes the valves V1 and V2 and controls the driving device 81 (not illustrated in FIG. 6A) of the top plate 35 to lower the top plate 35, thereby reducing the volume of the diffusion chamber 38. When the opening 7 is closed and the volume of the gas diffusion chamber 38 is reduced, the controller 60 controls the exhaust device 2 to exhaust the gas from the processing chamber 5 through the exhaust outlet 6 such that an atmosphere of the processing chamber 5 has a predetermined degree of vacuum (Step 1 in FIG. 7). In Step 1, the top plate 35 is positioned at a lower position (Low), the valves V1 and V2 are closed, and the valves V5 and V6 are opened, and the gas A and the gas B are stored in the gas buffers 44 and 45, respectively. When the exhausting is completed, the controller 60 controls the driving device 81 of the top plate 35 to lift the top plate 35. The controller 60 moves the top plate 35 to the upper position (High) to increase the volume of the gas diffusion chamber 38 (Step 2 in FIG. 7).

Next, as illustrated in FIG. 6B, the controller 60 controls the valve V1 such that the valve V1 is opened, and the gas A stored in the gas buffer 44 is supplied to the gas inlet 40. The gas A is supplied from the gas inlet 40 to the gas diffusion chamber 38 and diffused in the gas diffusion chamber 38. After the gas A is diffused in the gas diffusion chamber 38, the gas A is supplied in a shower manner to the processing chamber 5 of the chamber 1 through the gas supply holes 39 (Step 3 in FIG. 7).

The controller 60 controls the power supply device 51 to supply the first radio-frequency power for plasma excitation to the stage 8. The controller 60 generates a plasma. The wafer W is processed by the plasma generated from the gas A in the processing chamber 5. For example, a film is formed on the wafer W by the plasma generated from the gas A. When the processing by the gas A is completed, the controller 60 controls the valve V1 such that the valve V1 is closed, and the supply of the gas A is stopped (Step 4 in FIG. 7). Since the valve V1 is closed, the gas A starts to be stored in the gas buffer 44. The controller 60 further controls the power supply device 51 to stop supplying a radio-frequency power to the processing chamber 5.

Subsequently, as illustrated in FIG. 6C, the controller 60 controls the driving device 81 (not illustrated in FIG. 6C) of the top plate 35 to lower the top plate 35, thereby reducing the volume of the gas diffusion chamber 38. When the volume of the gas diffusion chamber 38 is reduced, the controller 60 controls the exhaust device 2 to exhaust the gas A from the processing chamber 5 (Step 5 in FIG. 7). In Step 5, the top plate 35 is positioned at the lower position (Low), the valves V1 and V2 are closed, and the valves V5 and V6 are opened. When exhausting is completed, the controller 60 controls the driving device 81 of the top plate 35 to lift the top plate 35. The controller 60 moves the top plate 35 to the upper position (High) to increase the volume of the gas diffusion chamber 38 (Step 6 in FIG. 7).

Next, as illustrated in FIG. 6D, the controller 60 controls the valve V2 such that the valve V2 is opened, and the gas B stored in the gas buffer 45 is supplied to the gas inlet 40. The gas B is supplied from the gas inlet 40 to the gas diffusion chamber 38 and diffused in the gas diffusion chamber 38. After the gas B is diffused in the gas diffusion chamber 38, the gas B is supplied in a shower manner to the processing chamber 5 of the chamber 1 through the gas supply holes 39 (Step 7 in FIG. 7).

The controller 60 controls the power supply device 51 to supply the first radio-frequency power for plasma excitation and the second radio-frequency power for biasing to the stage 8. The controller 60 generates a plasma. The wafer W is processed by the plasma generated from the gas B in the processing chamber 5. For example, the wafer W is etched by the plasma generated from the gas B. When the processing by the gas B is completed, the controller 60 controls the valve V2 such that the valve V2 is closed, and the supply of the gas B is stopped (Step 8 in FIG. 7). In addition, the controller 60 controls the power supply device 51 to stop supplying a radio-frequency power to the processing chamber 5. The controller 60 then repeats the processing, for example, in a scheme such as exhaust, processing by gas A, exhaust, processing by gas B, and exhaust.

In Modification 2, since the gas A and the gas B stored in the gas buffers 44 and 45 are supplied when the process gas is supplied, not only the time for exhausting the process gas may be shortened, but also the time for supplying the process gas can be shortened. That is, in Modification 2, the processing time of the process can be shortened.

### Modification 3

The gas diffusion chamber 38 may be configured to be divided into regions, for example, a center portion and a peripheral portion, and respective volumes are changed by corresponding top plates. FIG. 8 is a view illustrating an example of a substrate processing apparatus according to Modification 3. FIG. 8 is an example of a substrate processing apparatus 10c in which the gas diffusion chamber 38 of the substrate processing apparatus 10 is divided into a first gas diffusion chamber 38a in the center and a second gas diffusion chamber 38b in the periphery, and top plates 35a and 35b are respectively provided. In the substrate processing apparatus 10c, the same configurations as those of the substrate processing apparatus 10 will be denoted as the same reference numerals, and descriptions of the repeated configurations and operations will be omitted.

Top plate supports 32a and 32b are formed of, for example, aluminum. The top plate support 32b is formed in a cylindrical shape that may be disposed on or above the side wall of the chamber 1 and is anodized (anodic oxidation treatment) on its surface. The top plate support 32a is located closer to the center than the top plate support 32b is thereto, is formed in a cylindrical shape that may be disposed in the center of a shower plate 33a and is anodized (anodic oxidation treatment) on its surface. The top plate supports 32a and 32b are connected to the top plates 35a and 35b through bellows 37a and 37b, respectively.

The shower plate 33a is formed of a conductor and is formed in a disc shape. The shower plate 33a is disposed such that it faces the stage 8 and a lower surface of the shower plate 33a is substantially parallel to an upper surface of the stage 8. The shower plate 33a is also disposed to close the opening formed in the ceiling of the chamber 1. The shower plate 33a is supported by the chamber 1 through the top plate support 32b such that the shower plate 33a and the chamber 1 are electrically connected to each other.

The top plates 35a and 35b are formed of a conductor, the top plate 35a is formed in a disc shape, and the top plate 35b is formed in a donut shape concentric with the top plate 35a. The top plates 35a and 35b are disposed such that they face the shower plate 33a and lower surfaces of the top plates 35a and 35b are substantially parallel to an upper surface of the shower plate 33a. In addition, the top plates 35a and 35b have driving devices 81a and 81b, respectively. Sealing members 36a and 36b move together with the top plates 35a and 35b when the top plates 35a and 35b move up and down, while maintaining the airtightness between the periphery of the top plates 35a and 35b and the top plate supports 32a and 32b, respectively. The top plates 35a and 35b form the first gas diffusion chamber 38a and the second gas diffusion chamber 38b, together with the top plate supports 32a and 32b, the shower plate 33a, and the sealing members 36a and 36b, respectively.

The bellows 37a and 37b are formed to be expansible. The bellows 37a and 37b connect with flanges portion of the top plate supports 32a and 32b and upper surfaces of the top plates 35a and 35b, respectively. The top plates 35a and 35b are moved up and down by the driving devices 81a and 81b, respectively. That is, in the substrate processing apparatus 10c, the top plates 35a and 35b individually move up and down to change volumes of the first gas diffusion chamber 38a and the second gas diffusion chamber 38b, respectively.

In the shower plate 33a, gas supply holes 39 are formed to communicate the processing chamber 5 with the first gas diffusion chamber 38a or the second gas diffusion chamber 38b. A gas inlet 46 is formed in the center of the top plate 35a and communicates with the first gas diffusion chamber 38a. A gas inlet 47 is formed in the periphery of the top plate 35b and communicates with the second gas diffusion chamber 38b.

In the substrate processing apparatus 10c, the process gas sources 41 and 42 are connected to the gas inlets 46 and 47 through gas pipes, respectively having valves V7 and V8, and gas inlet tubes, respectively. That is, the gas inlet tube has a first gas inlet tube for introducing a gas into the first gas diffusion chamber 38a, and a second gas inlet tube for introducing a gas into the second gas diffusion chamber 38b. The process gas source 41 and the first gas inlet tube are connected to each other through a first gas pipe having the valve V7. The first gas inlet tube is connected to the gas inlet 46. The process gas source 42 and the second gas inlet tube are connected to each other through a second gas pipe having the valve V8. The second gas inlet tube is connected to the gas inlet 47.

The process gas sources 41 and 42 supply a predetermined process gas to the gas inlets 46 and 47. In the substrate processing apparatus 10c, for example, process gases of the same kind but having different concentrations may be supplied from the process gas sources 41 and 42 to the first gas diffusion chamber 38a and the second gas diffusion chamber 38b, respectively. In the substrate processing apparatus 10c, different kinds of process gases may be supplied to the first gas diffusion chamber 38a and the second gas diffusion chamber 38b, respectively. That is, the substrate processing apparatus 10c may concurrently supply a plurality of process gases to the processing chamber 5.

In the substrate processing method described above, the time for exhausting the process gas is shortened by lowering the top plate 35 when the process gas is exhausted, but the present embodiment is not limited thereto. For example, the top plate 35 may not be lowered, and the stage 8 may be lifted to reduce the volume of the processing chamber 5, thereby shortening the time for exhausting the process gas.

As set forth hereinabove, according to the present embodiment, a substrate processing apparatus 10 has a processing chamber 5, a gas supply 31, a gas inlet tube 43 and a gas source. The processing chamber 5 accommodates a substrate. The gas supply 31 has a gas diffusion chamber 38 and gas holes (gas supply holes 39) that communicate the gas diffusion chamber 38 with the processing chamber 5. The gas inlet tube 43 is at least one gas inlet tube for introducing a gas into the gas diffusion chamber 38 of the gas supply 31. The gas source is connected to the gas inlet tube 43 and supplies the gas to the gas inlet tube 43. In addition, the gas supply 31 has a volume-variable device for changing a volume in the gas diffusion chamber 38. Accordingly, the time for exhausting the process gas can be shortened.

In addition, according to the present embodiment, the gas diffusion chamber 38 has a top plate 35, and the volume-variable device changes the volume by moving the top plate 35 up and down. Accordingly, the time for exhausting the process gas in the gas diffusion chamber 38 can be shortened.

In addition, according to the present embodiment, the processing chamber 5 has a top plate support 32 and has an expansible portion (bellows 37) for connecting the top plate 35 and the top plate support 32. Accordingly, the top plate 35 can move up and down.

In addition, according to the present embodiment, a part of the gas inlet tube 43 is expansible or movable. Accordingly, the process gas can be provided, although the top plate 35 moves up and down.

In addition, according to the present embodiment, the gas source has a first gas source for suppling a first gas and a second gas source for supplying a second gas. Accordingly, the time for exhausting each of process gases can be shortened.

In addition, according to the present embodiment, the first gas source and the gas inlet tube 43 are connected to each other through a first gas pipe having a first valve, and the second gas source and the gas inlet tube 43 are connected to each other through a second gas pipe having a second valve. Accordingly, a plurality of process gases can be supplied.

In addition, according to Modification 2, a first gas buffer is provided between the first valve and the first gas source, and a second gas buffer is provided between the second valve and the second gas source. Accordingly, the time for supplying the process gas can be shortened

In addition, according to Modification 3, the gas diffusion chamber has top plates 35a and 35b which have been divided into regions, and is divided into a first gas diffusion chamber 38a and a second gas diffusion chamber 38b respectively corresponding to the top plates. The gas inlet tube has a first gas inlet tube for introducing a gas into the first gas diffusion chamber 38a, and a second gas inlet tube for introducing a gas into the second gas diffusion chamber 38b. The first gas source and the first gas inlet tube are connected to each other through a first gas pipe having a first valve. The second gas source and the second gas inlet tube are connected to each other through a second gas pipe having a second valve. The volume-variable device individually moves the top plates 35a and 35b up and down to change volumes of the first gas diffusion chamber 38a and the second gas diffusion chamber 38b, respectively. Accordingly, a plurality of process gases can be concurrently supplied to the processing chamber 5.

In addition, according to Modification 1, a stage 8 for placing a substrate provided in the processing chamber 5, and a driving device for moving the stage 8 up and down are provided. Accordingly, a volume of the processing chamber 5 can be reduced, and the time for exhausting the process gas may be further shortened.

In addition, according to the present embodiment, a substrate processing method has a first gas supply process of supplying a first gas to a gas diffusion chamber 38, a compression process of reducing a volume of the gas diffusion chamber 38, and an expansion process of increasing the volume of the gas diffusion chamber 38. Accordingly, the time for exhausting the process gas can be further shortened.

In addition, according to the present embodiment, a second gas supply process of supplying a second gas to the gas diffusion chamber 38 is performed after the expansion process. Accordingly, process gases can be exchanged to perform processing.

In addition, according to Modification 1, a lowering process of lowering a stage 8 for placing a substrate is performed before the first gas supply process. Accordingly, a volume of the processing chamber 5 can be secured.

In addition, according to Modification 1, a lifting process of lifting the stage 8 is performed between the first gas supply process and the second gas supply process. Accordingly, the volume of the processing chamber 5 can be secured before the second gas supply process.

In addition, according to the present embodiment, a first gas stop process of stopping the supply of the first gas to the gas diffusion chamber 38 is performed between the first gas supply process and the compression process. Accordingly, the first gas in the gas diffusion chamber 38 can be supplied to the processing chamber 5.

In addition, according to the present embodiment, a second gas stop process of stopping the supply the second gas to the gas diffusion chamber 38 and a second compression process of reducing the volume of the gas diffusion chamber 38 are performed after the second gas supply process. Accordingly, the second gas in the gas diffusion chamber 38 can be supplied to the processing chamber 5, while the time for exhausting the second gas can be shortened.

In addition, according to the present embodiment, a second expansion process of increasing the volume of the gas diffusion chamber 38 is performed after the second compression process. Accordingly, the first gas can be supplied to the gas diffusion chamber 38 in a next first gas supply process.

In addition, according to the present embodiment, processes from the first gas supply process to the second expansion process are repeated several times. Accordingly, the time for exhausting the process gas can be shortened in the repeated processing.

In addition, according to Modification 2, in the first gas supply process, the first gas is collected in a first gas buffer 44 connected in front of the gas diffusion chamber 38, and when the first gas is supplied to the gas diffusion chamber 38, the first gas collected in the first gas buffer 44 is supplied to the gas diffusion chamber 38. Accordingly, not only the time for exhausting the process gas can be shortened, but also the time for supplying the process gas can be shortened.

In addition, according to Modification 2, in the second gas supply process, the second gas is collected in a second gas buffer 45 connected in front of the gas diffusion chamber 38, and when the second gas is supplied to the gas diffusion chamber 38, the second gas collected in the second gas buffer 45 is supplied to the gas diffusion chamber 38. Accordingly, not only the time for exhausting the process gas can be shortened, but also the time for supplying the process gas can be shortened.

In addition, although the capacitively coupled plasma processing apparatus has been described as an example of the substrate processing apparatus 10 in the above-described embodiment, embodiments are not limited thereto. For example, any plasma source such as an inductively coupled plasma, a microwave plasma, or a magnetron plasma may be used as the plasma source.

In addition, although the plasma processing apparatus has been described as an example of the substrate processing apparatus 10 in the above-described embodiment, embodiments are not limited thereto. For example, the present disclosure may be applied to a substrate processing apparatus that performs processing by alternately repeating process gases, without using a plasma, such as an atomic layer deposition (ALD) scheme.

According to the present disclosure, the time for exhausting a process gas may be shortened.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a processing chamber configured to accommodate a substrate,
a gas supply having a gas diffusion chamber and a plurality of gas holes that communicates the gas diffusion chamber with the processing chamber;
at least one gas inlet tube configured to introduce a gas into the gas diffusion chamber of the gas supply; and
a gas source connected to the gas inlet tube and configured to supply the gas to the gas inlet tube,
wherein the gas supply has a volume-variable device configured to change a volume in the gas diffusion chamber.

2. The substrate processing apparatus according to claim 1, wherein the gas diffusion chamber has a top plate, and
the volume-variable device moves the top plate up and down to change the volume.

3. The substrate processing apparatus according to claim 2, wherein the processing chamber has a top plate support and an expansible portion that connects the top plate and the top plate support.

4. The substrate processing apparatus according to claim 1, wherein a part of the gas inlet tube is expansible or movable.

5. The substrate processing apparatus according to claim 1, wherein the gas source includes a first gas source configured to supply a first gas and a second gas source configured to supply a second gas.

6. The substrate processing apparatus according to claim 5, wherein the first gas source and the gas inlet tube are connected to each other through a first gas pipe having a first valve, and
the second gas source and the gas inlet tube are connected to each other through a second gas pipe having a second valve.

7. The substrate processing apparatus according to claim 6, wherein a first gas buffer is provided between the first valve and the first gas source, and
a second gas buffer is provided between the second valve and the second gas source.

8. The substrate processing apparatus according to claim 5, wherein the gas diffusion chamber has a plurality of divided top plates each having a region, and is divided into a first gas diffusion chamber and a second gas diffusion chamber respectively corresponding to the plurality of divided top plates,
the gas inlet tube includes a first gas inlet tube configured to introduce a gas into the first gas diffusion chamber, and a second gas inlet tube configured to introduce a gas into the second gas diffusion chamber,
the first gas source and the first gas inlet tube are connected to each other through a first gas pipe having a first valve,
the second gas source and the second gas inlet tube are connected to each other through a second gas pipe having a second valve, and
the volume-variable device individually moves the plurality of top plates up and down to change volumes of the first gas diffusion chamber and the second gas diffusion chamber, respectively.

9. The substrate processing apparatus according to claim 1, further comprising:
a stage configured to place thereon a substrate provided in the processing chamber; and
a driver configured to move the stage up and down.

10. A substrate processing method comprising:
supplying a first gas to a gas diffusion chamber as a first gas supply process,
reducing a volume of the gas diffusion chamber as a first compression process, and
increasing the volume of the gas diffusion chamber as a first expansion process.

11. The substrate processing method according to claim 10, further comprising:
supplying a second gas to the gas diffusion chamber as a second gas supply process after the first expansion process.

12. The substrate processing method according to claim 11, further comprising:
moving down a stage that places thereon a substrate as a lowering process before the first gas supply process.

13. The substrate processing method according to claim 12, further comprising:
moving up the stage as a lifting process between the first gas supply process and the second gas supply process.

14. The substrate processing method according to claim 11, further comprising:
stopping the supply of the first gas to the gas diffusion chamber as a first gas stop process, between the first gas supply process and the first compression process.

15. The substrate processing method according to claim 11, further comprising:
stopping the supply of the second gas to the gas diffusion as a second stop process, after the second gas supply process; and
further reducing the volume of the gas diffusion chamber as a second compression process.

16. The substrate processing method according to claim 15, further comprising:
further increasing the volume of the gas diffusion chamber as a second expansion process, after the second compression process.

17. The substrate processing method according to claim 16, wherein processes from the first gas supply process to the second expansion process are repeated multiple times.

18. The substrate processing method according to claim 11, wherein in the first gas supply process, the first gas is collected in a first gas buffer connected in front of the gas diffusion chamber, and when the first gas is supplied to the gas diffusion chamber, the first gas collected in the first gas buffer is supplied to the gas diffusion chamber.

19. The substrate processing method according to claim 11, wherein in the second gas supply process, the second gas is collected in a second gas buffer connected in front of the gas diffusion chamber, and when the second gas is supplied to the gas diffusion chamber, the second gas collected in the second gas buffer is supplied to the gas diffusion chamber.
